(19) United States
(12) Patent Application Publication
(10) Pub. No.: US 2025/0098510 A1
(43) Pub. Date: Mar. 20, 2025

(54) METHOD FOR SEALING ORGANIC EL ELEMENT

(71) Applicants: KABUSHIKI KAISHA TOKAI RIKA DENKI SEISAKUSHO, Aichi (JP); NATIONAL UNIVERSITY CORPORATION YAMAGATA UNIVERSITY, Yamagata (JP)

(72) Inventors: Naoki NOBATA, Aichi (JP); Ryoga SUZUKI, Aichi (JP); Fumiya NAGAO, Aichi (JP); Yoshiyuki SUZURI, Yamagata (JP); Tetsushi MURAKAMI, Hiroshima (JP)

(73) Assignees: KABUSHIKI KAISHA TOKAI RIKA DENKI SEISAKUSHO, Aichi (JP); NATIONAL UNIVERSITY CORPORATION YAMAGATA UNIVERSITY, Yamagata (JP)

(21) Appl. No.: 18/706,923

(22) PCT Filed: Dec. 9, 2022
(86) PCT No.: PCT/JP2022/045399

§ 371 Date: May 2, 2024

(30) Foreign Application Priority Data
Dec. 15, 2021 (JP) 2021-203297

(51) Int. Cl. H10K 71/13; H10K 71/40; H10K 85/10; H10K 85/40

(52) U.S. Cl. CPC H10K 71/135; H10K 71/421; H10K 85/10; H10K 85/40

(57) ABSTRACT

A method for sealing an organic EL element, the method including: a step in which a stress relaxation layer is formed by at least applying a polymer material that contains an organic group in the structure to a base material, on which an organic EL element is provided, so as to cover the organic EL element; and a step in which a barrier layer is formed by at least applying an inorganic material to the stress relaxation layer, thereby forming a multilayer sealing film that comprises the stress relaxation layer and the barrier layer.

### TECHNICAL FIELD

The present invention relates to a method for sealing an organic EL element, an organic EL element, an organic EL device, and a device for vehicles.

### BACKGROUND ART

In recent years, organic electroluminescent elements (hereinafter also referred to as organic EL elements) have been increasingly used in display devices or lighting devices. Organic EL elements have good color development and low power consumption, and are therefore expected to be next-generation light-emitting elements.

On the other hand, in organic EL elements, an organic material constituting an organic EL element may deteriorate when it comes into contact with moisture or oxygen, which may leads to a decrease in performance. For that reason, for example, Patent Literature 1 to 4 below disclose techniques for preventing external moisture or oxygen from coming into contact with an organic EL element by sealing the organic EL element with a sealing film.

### CITATION LIST

### Patent Literature

Patent Literature 1: JP 2019-050220 A
Patent Literature 2: JP 2015-125955 A
Patent Literature 3: JP 2012-064435 A
Patent Literature 4: WO 2017/033440 A1

### SUMMARY OF INVENTION

### Technical Problem

However, in the techniques disclosed in Patent Literature 1 to 4 mentioned above, sufficient consideration is not given to the cost of forming the sealing film. For that reason, there has been a need for a method for sealing an organic EL element at a lower cost.

Therefore, the present invention has been made in view of the above problems, and an objective of the present invention is to provide a new and improved sealing method in which an organic EL element can be sealed at a lower cost, the organic EL element sealed using the sealing method, an organic EL device, and a device for vehicles.

### Solution to Problem

In order to solve the above problem, an aspect of the present invention provides a method for sealing an organic EL element, comprising: forming a stress relaxation layer by at least applying a polymer material that contains an organic group in its structure onto a base material, on which the organic EL element is provided, to cover the organic EL element; and forming a barrier layer by at least applying an inorganic material on the stress relaxation layer, thereby forming a multilayer sealing film that includes the stress relaxation layer and the barrier layer.

As described above, according to the present invention, it is possible to seal an organic EL element at a lower cost.

### BRIEF DESCRIPTION OF DRAWINGS

FIG. 1 is a schematic vertical cross-sectional view for explaining a sealing structure of an organic EL element according to an embodiment of the present invention.

FIG. 2 is a schematic vertical cross-sectional view for explaining a specific shape of a multilayer sealing film.

FIG. 3 is a schematic vertical cross-sectional view for explaining a modified example of the sealing structure of the organic EL element.

FIG. 4 is a schematic diagram showing a formation process of a stress relaxation layer.

FIG. 5 is a schematic diagram showing a formation process of a barrier layer.

FIG. 6 is an explanatory diagram showing changes in film thickness and refractive index of a PDMS solid film with respect to VUV irradiation time.

FIG. 7 is an explanatory diagram showing changes in film thickness and refractive index of a PHPS layer with respect to VUV irradiation time.

FIG. 8 is a graph diagram showing evaluation results of brightness stability of organic EL elements according to Example 1 and Comparative Examples 1 to 3.

FIG. 9 is a table showing evaluation results of sealing reliability of organic EL elements according to Examples 1 to 2 and Comparative Examples 1 to 3.

### DESCRIPTION OF EMBODIMENTS

Hereinafter, referring to the appended drawings, preferred embodiments of the present invention will be described in detail. It should be noted that, in this specification and the appended drawings, structural elements that have substantially the same function and structure are denoted with the same reference numerals, and repeated explanation thereof is omitted.

### <1. Sealing Structure of Organic EL Element>

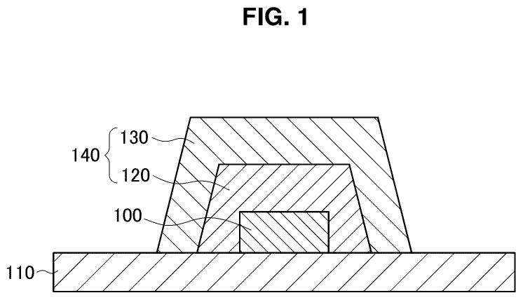

First, with reference to FIG. 1, a sealing structure of an organic EL element according to an embodiment of the present invention will be described. FIG. 1 is a schematic vertical cross-sectional view for explaining the sealing structure of the organic EL element according to the present embodiment.

As shown in FIG. 1, according to the sealing structure of the organic EL element according to the present embodiment, an organic EL element 100 provided on a base material 110 is sealed by a multilayer sealing film 140 including a stress relaxation layer 120 and a barrier layer 130.

The base material 110 is a support on which the organic EL element 100 is provided. As an example, the base material 110 may be a plate-shaped substrate made of silicon, quartz, glass, or the like. In addition, as another example, the base material 110 may be a film-like base material provided with gas barrier properties for inhibiting entrance of an external liquid or gas. Specifically, the base material 110 may include a polyethylene terephthalate (PET) resin film or a polyethylene naphthalate (PEN) resin film provided with a gas barrier layer on one or both sides. The gas barrier layer can be configured by, for example, alternately laminating oxides or nitrides of Si, Al, Zn, Sn, or the like and thermosetting resins such as epoxy resins or silicone resins.

The organic EL element 100 is configured by interposing an organic light-emitting layer between a pair of electrodes. Specifically, the organic EL element 100 may be configured by sequentially laminating a lower electrode, an organic light-emitting layer, and an upper electrode from the base material 110 side. The organic EL element 100 can cause a light-emitting material contained in the organic light-emitting layer to emit light by applying a voltage to the organic light-emitting layer through the lower electrode and the upper electrode. Specifically, in the organic EL element 100, by applying a voltage between the lower electrode and the upper electrode, holes are injected from one of the lower electrode and the upper electrode (that is, an anode), and electrons are injected from the other of the lower electrode and the upper electrode (that is, a cathode). Thus, the organic EL element 100 can cause the injected holes and electrons to recombine in the organic light-emitting layer, thereby causing the light-emitting material contained in the organic light-emitting layer to emit light with the energy generated by the recombination.

The lower electrode and the upper electrode are configured to include a conductive material. Specifically, the lower electrode and the upper electrode may be formed as transparent electrodes using a transparent conductive material such as indium tin oxide (ITO), or may be formed as reflective electrodes using a metal such as Al, Ag, or Mg or an alloy material thereof. For example, the lower electrode and the upper electrode may both be formed as transparent electrodes. Also, when light is extracted from the base material 110 side, the lower electrode may be configured as a transparent electrode, and the upper electrode may be configured as a reflective electrode. Further, when light is extracted from the multilayer sealing film 140 side, the upper electrode may be configured as a transparent electrode, and the lower electrode may be configured as a reflective electrode.

The organic light-emitting layer may be configured by laminating at least a hole transport layer, a light-emitting layer, and an electron transport layer in order from a side of the lower electrode or the upper electrode corresponding to an anode. The hole transport layer is configured to include, for example, α-NPD (diphenylnaphthyl diamine) or TPD (triphenyl diamine). The light-emitting layer is configured to include a light-emitting material such as an aluminum quinolinol complex (Alq₃) or a beryllium quinolinol complex (BeBq₂). The electron transport layer is configured to include, for example, an aluminum quinolinol complex (Alq₃).

Also, the organic light-emitting layer may further include a hole injection layer between the lower electrode or the upper electrode and the hole transport layer. The hole injection layer includes, for example, MoO₃ or the like. Further, the organic light-emitting layer may include an electron injection layer between the lower electrode or the upper electrode and the electron transport layer. The electron injection layer includes, for example, LiF or the like.

The stress relaxation layer 120 is formed by at least applying a polymer material containing an organic group in its structure onto the base material 110 to cover the organic EL element 100. The stress relaxation layer 120 includes a layer made of a flexible polymer material, and thus stress generated between the barrier layer 130 and the organic EL element 100 can be relaxed. According to this, the stress relaxation layer 120 can improve adhesion between the barrier layer 130 and the organic EL element 100.

A polymer material containing an organic group in its structure includes a polymer material that has a functional group (that is, an organic group) containing carbon in its main chain or side chain and is composed of repeating basic units. As an example, the polymer material containing an organic group in its structure may include an organic polymer material such as an acryl-based resin, a polyester-based resin, or a polyamide-based resin. Also, as another example, the polymer material containing an organic group in its structure may include an organic siloxane resin containing an organic group in its side chain. For example, the stress relaxation layer 120 may include a layer formed by applying polydimethylsiloxane, which is an organic siloxane resin, onto the base material 110 to cover the organic EL element 100.

A viscosity of the polymer material may be 5 mPa·s or more and 20 mPa·s at 25° C. When the viscosity of the polymer material is 5 mPa·s or more and 20 mPa·s at 25° C., the stress relaxation layer 120 can be appropriately formed by application thereof. Moreover, the stress relaxation layer 120 can appropriately relieve the stress generated between the barrier layer 130 and the organic EL element 100 by having appropriate viscoelasticity. The viscosity of the polymer material can be measured, for example, with a rheometer.

A thickness of the stress relaxation layer 120 may be 50 nm or more and 500 nm or less. The thickness of the stress relaxation layer 120 can be acquired, for example, by measuring the stress relaxation layer 120 deposited immediately above the organic EL element 100 using spectroscopic ellipsometry or the like. When the thickness of the stress relaxation layer 120 is 50 nm or more and 500 nm or less, the stress relaxation layer 120 can improve the adhesion between the barrier layer 130 and the organic EL element 100 without reducing light extraction efficiency from the multilayer sealing film 140 side of the organic EL element 100.

A refractive index of the stress relaxation layer 120 may be 1.4 or more and 1.5 or less. The refractive index of the stress relaxation layer 120 is an average refractive index of the entire stress relaxation layer 120 and can be measured by, for example, spectroscopic ellipsometry. When the refractive index of the stress relaxation layer 120 is 1.4 or more and 1.5 or less, the stress relaxation layer 120 can further increase the light extraction efficiency from the multilayer sealing film 140 side of the organic EL element 100.

Also, the stress relaxation layer 120 may be formed by applying a mixture of a polymer material containing an organic group in its structure and another material onto the base material 110 to cover the organic EL element 100. Further, the stress relaxation layer 120 may have a multilayer structure including a layer made of the above-mentioned polymer material and at least one other layer.

The barrier layer 130 is formed by at least applying an inorganic material onto the stress relaxation layer 120. The barrier layer 130 can prevent moisture or oxygen from entering the organic EL element 100 by including a layer made of a dense inorganic material with excellent gas barrier properties.

As an example, the inorganic material may include perhydropolysilazane. Perhydropolysilazane can be dissolved in an organic solvent, or the like and easily applied, and after application, can be formed into a glass-like film containing SiOₓ, SiOₓN_{y}, SiNₓ, or the like by reacting with external moisture. As another example, the inorganic material may include Al₂O₃, Ta₂O₅, HfO₂, ZrO₂, SBT (strontium bismuthate tantalate), or PZT (lead zirconate titanate).

A thickness of the barrier layer 130 may be 50 nm or more and 300 nm or less. The thickness of the barrier layer 130 can be acquired, for example, by measuring the barrier layer 130 deposited immediately above the organic EL element 100 using spectroscopic ellipsometry or the like. When the thickness of the barrier layer 130 is 50 nm or more and 300 nm or less, the barrier layer 130 can prevent moisture or oxygen from entering the organic EL element 100 without reducing the light extraction efficiency from the multilayer sealing film 140 side of the organic EL element 100.

A refractive index of the barrier layer 130 may be 1.6 or more. The refractive index of the barrier layer 130 is the average refractive index of the entire barrier layer 130, and can be measured by, for example, spectroscopic ellipsometry. When the refractive index of the barrier layer 130 is 1.6 or more, the barrier layer 130 can further increase the light extraction efficiency from the multilayer sealing film 140 side of the organic EL element 100. Also, an upper limit of the refractive index of the barrier layer 130 is not particularly limited, but may be set to, for example, 2.0.

Also, the barrier layer 130 may be formed by applying a mixture of an inorganic material and another material onto the stress relaxation layer 120. Further, the barrier layer 130 may be configured of a multilayer structure having a layer made of the above-mentioned inorganic material and at least one other layer.

The multilayer sealing film 140 including the stress relaxation layer 120 and the barrier layer 130 can seal the organic EL element 100 by covering upper and side surfaces of the organic EL element 100. According to this, the multilayer sealing film 140 can ensure the adhesion between the barrier layer 130 and the organic EL element 100 with the stress relaxation layer 120 while preventing external moisture or oxygen from entering the organic EL element 100 with the barrier layer 130. Since the multilayer sealing film 140 is formed through a coating process, which is cheaper than a vapor deposition process, it is possible to seal the organic EL element 100 at a lower cost.

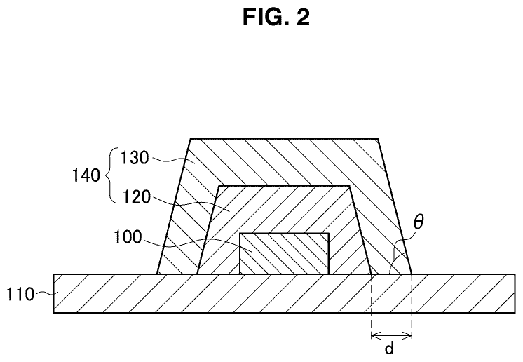

Next, a specific shape of the multilayer sealing film 140 will be described with reference to FIG. 2. FIG. 2 is a schematic vertical cross-sectional view for explaining the specific shape of the multilayer sealing film 140.

As shown in FIG. 2, the multilayer sealing film 140 including the stress relaxation layer 120 and the barrier layer 130 is provided in a three-dimensional shape tapered in a direction away from the base material 110. Specifically, the multilayer sealing film 140 may be provided in a tapered shape with a taper angle of 10° or more and 80° or less. In a cross-sectional image of the organic EL element 100 photographed with a scanning electron microscope (SEM) or the like, when an outer shape of the barrier layer 130 facing the outside is approximated with straight lines, the taper angle of the multilayer sealing film 140 can be calculated as an angle θ between an approximated straight line of the outer shape of the barrier layer 130 and a surface of the base material 110. Since the multilayer sealing film 140 is provided in a tapered three-dimensional shape, it can cover the side surfaces of the organic EL element 100 more reliably, thereby preventing external moisture or oxygen from entering the organic EL element 100 more reliably.

Also, end portions of the stress relaxation layer 120 and the barrier layer 130 that come into contact with the base material 110 may be separated from each other by 1 μm or more. Specifically, since the multilayer sealing film 140 has a tapered shape, the stress relaxation layer 120 and the barrier layer 130 come into contact with the base material 110 obliquely. In this case, a distance d between the end portions of the stress relaxation layer 120 and the barrier layer 130 on a side away from the organic EL element 100 may be 1 μm or more. When the distance d between the end portions in contact with the base material 110 is 1 μm or more, the stress relaxation layer 120 and the barrier layer 130 can cover the organic EL element 100 in a tapered shape with a wider skirt. According to this, the multilayer sealing film 140 can more reliably cover the side surfaces of the organic EL element 100, and thus can more reliably prevent external moisture or oxygen from entering the organic EL element 100.

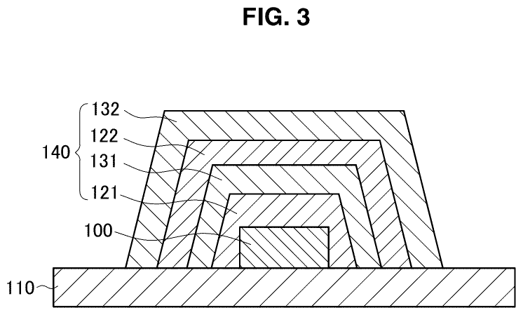

Next, a modified example of the sealing structure of the organic EL element 100 according to the present embodiment will be described with reference to FIG. 3. FIG. 3 is a schematic vertical cross-sectional view for explaining the modified example of the sealing structure of the organic EL element 100.

As shown in FIG. 3, in the modified example of the sealing structure of the organic EL element 100, the multilayer sealing film 140 is provided to have a structure in which a first stress relaxation layer 121, a first barrier layer 131, a second stress relaxation layer 122, and a second barrier layer 132 are laminated from the organic EL element 100 side. The first stress relaxation layer 121 and the second stress relaxation layer 122 are substantially the same as the stress relaxation layer 120 described above. Materials and structures constituting the first stress relaxation layer 121 and the second stress relaxation layer 122 may be the same as or different from each other. The first barrier layer 131 and the second barrier layer 132 are substantially the same as the barrier layer 130 described above. Materials and structures forming the first barrier layer 131 and the second barrier layer 132 may be the same as or different from each other.

That is, in the modified example of the sealing structure of the organic EL element 100, the multilayer sealing film 140 is provided by alternately and repeatedly laminating a plurality of stress relaxation layers 120 and barrier layers 130. By providing such a multilayer structure, the multilayer sealing film 140 can more reliably prevent external moisture or oxygen from entering the organic EL element 100 with the plurality of barrier layers 130.

The number of repeated layers of the stress relaxation layer 120 and the barrier layer 130 in the multilayer sealing film 140 may be 2 or more and 4 or less. In such a case, the multilayer sealing film 140 can more reliably prevent external moisture or oxygen from entering the organic EL element 100 without reducing the light extraction efficiency from the organic EL element 100 to be sealed.

Also, a total thickness of the multilayer sealing film 140 provided with a repeated multilayer structure of the stress relaxation layer 120 and the barrier layer 130 may be 1 μm or more. In such a case, the multilayer sealing film 140 can more reliably prevent external moisture or oxygen from entering the organic EL element 100. In addition, diameters of major particles floating in the atmosphere are 0.5 μm to 2 μm, and thus by setting the total thickness of the multilayer sealing film 140 to 1 μm or more, it is also possible to prevent the particles from entering the inside of the multilayer sealing film 140. Further, the total thickness of the multilayer sealing film 140 can be acquired, for example, by measuring the multilayer sealing film 140 deposited immediately above the organic EL element 100 using spectroscopic ellipsometry or the like.

Furthermore, in the multilayer sealing film 140 provided with a repeated multilayer structure of the stress relaxation layer 120 and the barrier layer 130, end portions of each layer (that is, the first stress relaxation layer 121, the first barrier layer 131, the second stress relaxation layer 122, and the second barrier layers 132) that come into contact with the base material 110 may be separated from end portions of adjacent layers by 1 μm or more. In other words, the multilayer sealing film 140 may be provided in a tapered shape with a wider skirt so that contact lengths of each layer constituting the multilayer sealing film 140 with the base material 110 are 1 μm or more. According to this, the multilayer sealing film 140 can more reliably cover the side surfaces of the organic EL element 100, and thus can more reliably prevent external moisture or oxygen from entering the organic EL element 100.

The organic EL element 100 sealed by the method for sealing the organic EL element 100 according to the present embodiment can be used, for example, as a light source for a lighting device or a display device. In particular, according to the method for sealing the organic EL element 100 according to the present embodiment, the organic EL element 100 can more reliably prevent entrance of moisture or oxygen from the outside, and thus the organic EL element 100 can be suitably used for vehicle lighting, vehicle indicators, vehicle interface devices, and the like.

### <2. Method for Sealing Organic EL Element>

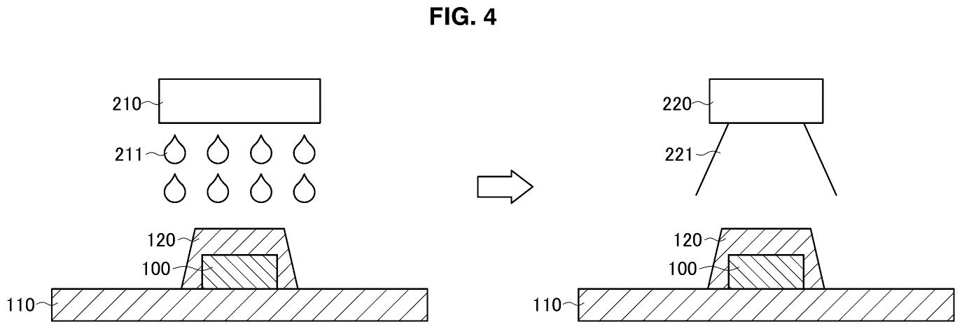

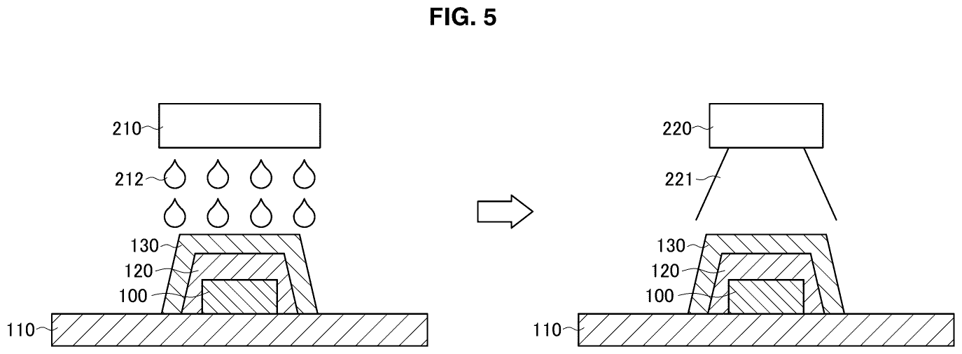

Next, a method for sealing the organic EL element 100 according to the present embodiment will be described with reference to FIGS. 4 and 5. FIG. 4 is a schematic diagram showing a formation process of the stress relaxation layer 120. FIG. 5 is a schematic diagram showing a formation process of the barrier layer 130.

As shown in FIGS. 4 and 5, the stress relaxation layer 120 and barrier layer 130 that constitute the multilayer sealing film 140 may be formed by applying using inkjet printing.

As shown in FIG. 4, the stress relaxation layer 120 may be provided by discharging the above-described polymer material 211 from an inkjet head 210 onto the base material 110 and the organic EL element 100 and covering the organic EL element 100 with the polymer material 211. The polymer material 211 discharged from the inkjet head 210 becomes a solid film by being cured by ultraviolet irradiation. After that, the solid film of the polymer material 211 is further modified by vacuum ultraviolet rays 221 radiated from a light source 220, thereby being formed as the stress relaxation layer 120.

Specifically, the polymer material 211 may be dissolved in a solvent in which the polymer material 211 has a higher solubility than that of the organic EL element 100, thereby being discharged from the inkjet head 210 to the base material 110 and the organic EL element 100. According to this, the polymer material 211 can be appropriately discharged from the inkjet head 210 while suppressing damage to the organic EL element 100.

For example, when the polymer material 211 contains polydimethylsiloxane, the polymer material 211 may be dissolved in a solvent containing decamethylcyclopentasiloxane and discharged from the inkjet head 210. Decamethylcyclopentasiloxane, also referred to as D5, is a cyclic siloxane with five siloxane bonds. Decamethylcyclopentasiloxane has an extremely poor solubility for the organic light-emitting layer included in the organic EL element 100, but has an excellent solubility for polydimethylsiloxane, and thus can be suitably used as a solvent for polydimethylsiloxane.

For example, the polymer material 211 may be applied to the base material 110 and the organic EL element 100 at a discharge amount of 2 μl or more and 5 μl or less per 1 cm². Since inkjet printing allows precise control of an amount of liquid discharged from the inkjet head 210, it is possible to form the stress relaxation layer 120 so as to sufficiently cover the top and side surfaces of the organic EL element 100.

The polymer material 211 discharged from the inkjet head 210 may be cured by being irradiated with ultraviolet rays including light with a wavelength of 365 nm and light with a wavelength of 254 nm. The cured solid film of the polymer material 211 may be further irradiated with the vacuum ultraviolet rays 221 including light with a wavelength of 172 nm, thereby being modified to become harder. The vacuum ultraviolet rays 221 including light with a wavelength of 172 nm are high-energy rays among ultraviolet rays, and thus can efficiently modify the solid film of the polymer material 211. For example, the polymer material 211 may be modified by being irradiated with the vacuum ultraviolet rays 221 at an accumulated light amount of 15,000 mJ/cm² or more.

Also, the polymer material 211 may be cured by being irradiated with ultraviolet rays and being heated. In such a case, since the solvent is removed from the polymer material 211 by heating, the polymer material 211 can be cured into the solid film in a shorter time. Heating may be performed at a temperature range of 150° C. or lower in which thermal damage to the organic EL element 100 is not caused.

As shown in FIG. 5, the barrier layer 130 may be provided by discharging the above-described inorganic material 212 onto the stress relaxation layer 120 from the inkjet head 210 and covering the stress relaxation layer 120 with the inorganic material 212. The inorganic material 212 discharged from the inkjet head 210 is cured by the vacuum ultraviolet rays 221 radiated from the light source 220, thereby being formed as the barrier layer 130.

Specifically, the inorganic material 212 may be dissolved in a solvent in which the inorganic material 212 has a higher solubility than that of the stress relaxation layer 120, thereby being discharged from the inkjet head 210 to the stress relaxation layer 120. According to this, the inorganic material 212 can be appropriately discharged from the inkjet head 210 while inhibiting damage to the stress relaxation layer 120.

For example, when the inorganic material 212 includes perhydropolysilazane, the inorganic material 212 may be dissolved in a solvent containing dibutyl ether (DBE) and discharged from the inkjet head 210. Dibutyl ether has an extremely poor solubility for the polymer material 211 constituting the stress relaxation layer 120, but has an excellent solubility for perhydropolysilazane, and thus can be suitably used as a solvent for perhydropolysilazane.

For example, the inorganic material 212 may be applied to the stress relaxation layer 120 at a discharge amount of 2 μl or more and 5 μl or less per 1 cm². Since inkjet printing allows precise control of the amount of liquid discharged from the inkjet head 210, it is possible to form the barrier layer 130 to sufficiently cover the stress relaxation layer 120.

The inorganic material 212 discharged from the inkjet head 210 may be cured by being irradiated with the vacuum ultraviolet rays 221 including light with a wavelength of 172 nm. The vacuum ultraviolet rays 221 including light with a wavelength of 172 nm are high-energy rays among ultraviolet rays, and thus can efficiently cure the inorganic material 212. For example, the inorganic material 212 may be cured by being irradiated with the vacuum ultraviolet rays 221 with an accumulated light amount of 15000 mJ/cm² or more.

Also, the inorganic material 212 may be cured by being irradiated with vacuum ultraviolet rays 221 and being heated. Since the solvent is removed by heating, the inorganic material 212 can be cured in a shorter time. Heating may be performed at a temperature range of 150° C. or lower in which thermal damage to the organic EL element 100 is not caused.

In the method for sealing the organic EL element 100 according to the present embodiment, both the stress relaxation layer 120 and the barrier layer 130 that seal the organic EL element 100 are formed using the same inkjet printing process. According to this, since the method for sealing the organic EL element 100 according to the present embodiment can form the stress relaxation layer 120 and the barrier layer 130 with a single device, it is possible to seal the organic EL element 100 at a lower cost.

In addition, in inkjet printing, the inkjet head 210 that discharges the polymer material 211 and the inorganic material 212 is moved by a piezo element. Since the piezo element can drive the inkjet head 210 with high precision, the polymer material 211 and the inorganic material 212 can be discharged with high positional accuracy to sufficiently cover the upper and side surfaces of the organic EL element 100.

Further, formation of the stress relaxation layer 120 and the barrier layer 130 may be performed under a nitrogen atmosphere. According to this, in the method for sealing the organic EL element 100 according to the present embodiment, it is possible to prevent moisture or oxygen from entering the organic EL element 100 when the stress relaxation layer 120 and the barrier layer 130 are formed.

### EXAMPLES

First, an example of applying and curing polydimethylsiloxane (PDMS) included in the polymer material constituting the stress relaxation layer will be described.

Specifically, two precursors of ultraviolet (UV) curable PDMS (X-34-4184A and X-34-4184B, Shin-Etsu) were mixed at a mass ratio of 1:1 for 4 minutes to obtain a viscous mixture. Next, the viscous mixture was diluted up to 9 times by weight with decamethylcyclopentasiloxane (D5, purity>99%, TCI) and applied onto a single crystal Si substrate using inkjet printing in a glove box under an N₂ atmosphere with oxygen and moisture concentrations below 10 ppm.

After applying, in order to evaporate excess D5, it was left to stand for about 5 minutes, and then UV generated by a high-pressure mercury lamp (wavelengths of 365 nm and 254 nm, and 40 mW/cm²) was irradiated for 60 seconds to form a solid film of PDMS. After that, vacuum ultraviolet rays (VUV) generated by a Xe excimer lamp (a wavelength of 172 nm, and 50 mW/cm²) was irradiated for 1 to 20 minutes. Thus, a stress relaxation layer made of PDMS was formed.

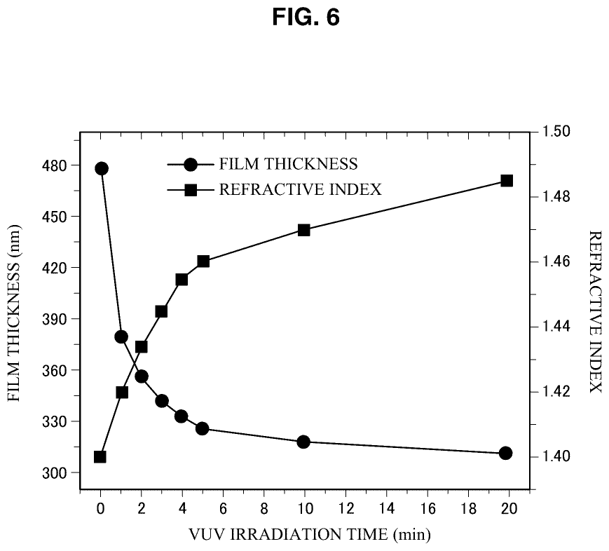

Subsequently, changes in film thickness and refractive index of the PDMS solid film with respect to VUV irradiation time were measured using multi-incident angle spectroscopic ellipsometry. The measurement results are shown in FIG. 6. FIG. 6 is an explanatory diagram showing the changes in film thickness and refractive index of the PDMS solid film with respect to VUV irradiation time. Also, the refractive index was measured using light with a wavelength of 800 nm.

As shown in FIG. 6, as the VUV irradiation time increases, the film thickness of the PDMS solid film decreases and the refractive index of the PDMS solid film increases. This is considered to be because the PDMS on the surface reacts with VUV irradiation and is converted into SiOₓ. It is considered that, when the accumulated light amount of VUV is 15,000 mJ/cm² or more (that is, when the irradiation time is 5 minutes or more), the changes in the film thickness and the refractive index of the PDMS solid film become gradual, and thus a composition of the PDMS solid film becomes almost stable. Further, it can be seen that, when the accumulated light amount of VUV is 15000 mJ/cm² or more, the film thickness and the refractive index of the PDMS solid film fall within a range suitable for the stress relaxation layer of the present embodiment.

Next, an example of applying and curing perhydropolysilazane (PHPS) included in the inorganic material constituting the barrier layer will be described.

Specifically, a 20% by mass dibutyl ether (DBE) solution of PHPS (NAX120-20, Merck Japan) was diluted with anhydrous DBE (99.3%, Sigma-Aldrich) so that it could be applied with an appropriate film thickness. Next, a DBE solution of PHPS was applied onto a single crystal Si substrate using inkjet printing in a glove box under a N₂ atmosphere with oxygen and water concentrations below 10 ppm.

After drying the applied PHPS and forming a PHPS layer, the PHPS layer was irradiated with vacuum ultraviolet rays (VUV) generated by a Xe excimer lamp (a wavelength of 172 nm, and 50 mW/cm²) for 1 to 20 minutes. Thus, a barrier layer made of PHPS was formed.

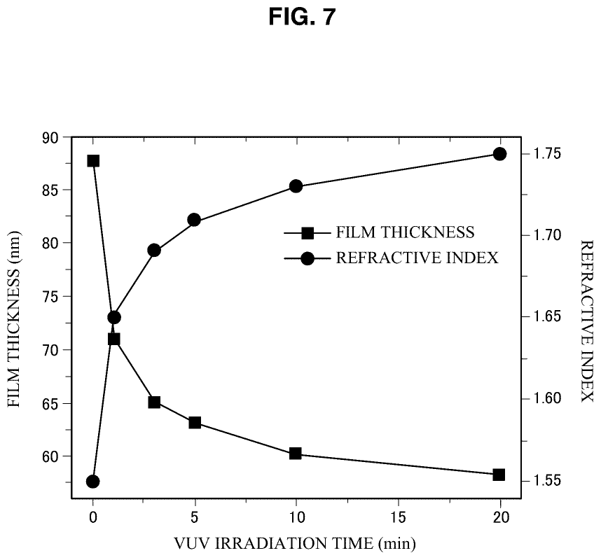

Subsequently, changes in film thickness and refractive index of the PHPS layer with respect to VUV irradiation time were measured using multi-incident angle spectroscopic ellipsometry. The measurement results are shown in FIG. 7. FIG. 7 is an explanatory diagram showing the changes in film thickness and refractive index of the PHPS layer with respect to VUV irradiation time. Also, the refractive index was measured using light with a wavelength of 800 nm.

As shown in FIG. 7, as the VUV irradiation time becomes longer, the film thickness of the PHPS layer decreases and the refractive index of the PHPS layer increases. This is considered to be because PHPS on the surface reacts with VUV irradiation and is converted to SiOₓ. It is considered that, when the accumulated light amount of VUV is 15000 mJ/cm² or more (that is, when the irradiation time is 5 minutes or more), the changes in the thickness and the refractive index of the PHPS layer become gradual, and thus the PHPS layer is almost stabilized. Further, it can be seen that, when the accumulated light amount of VUV is 15000 mJ/cm² or more, the film thickness and the refractive index of the PHPS layer fall within a range suitable for the barrier layer of the present embodiment.

Hereinafter, the method for sealing the organic EL element according to the present embodiment will be specifically described with further reference to examples and comparative examples. Also, the examples shown below are just illustrative, and the method for sealing the organic EL element according to the present embodiment is not limited to the examples below.

First, an organic EL element was produced on a base material. Specifically, an organic layer was formed by vacuum evaporation on a glass substrate on which ITO was formed, and an A1 film was further formed on the organic layer, thereby producing the organic EL element. A film structure of the organic EL element is set to ITO (150 nm)/HAT-CN (15 nm)/NPD (25 nm)/Ir(ppy)₃-doped CBP (35 nm)/BAlq (10 nm)/Alq₃ (40 nm)/LiF (0.7 nm)/A1 (100 nm) from the glass substrate side.

### Example 1

An organic EL element according to Example 1 was produced by sequentially laminating PDMS and PHPS on the organic EL element and sealing the organic EL element using the method described above. The VUV irradiation time for each of PDMS and PHPS was 20 minutes.

### Example 2

An organic EL element according to Example 2 was produced by sequentially laminating PDMS and PHPS alternately and repeatedly three times on the organic EL element and sealing the organic EL element using the method described above. The VUV irradiation time for each of PDMS and PHPS was 20 minutes.

### Comparative Example 1

An organic EL element according to Comparative Example 1 was produced by leaving the organic EL element as it was without sealing it.

### Comparative Example 2

An organic EL element according to Comparative Example 2 was produced by laminating only PDMS on the organic EL element and sealing the organic EL element using the method described above. The VUV irradiation time for PDMS was 20 minutes.

### Comparative Example 3

An organic EL element according to Comparative Example 3 was produced by bonding a glass substrate onto the organic EL element and sealing the organic EL element using a UV-curable epoxy resin.

### Reliability Evaluation

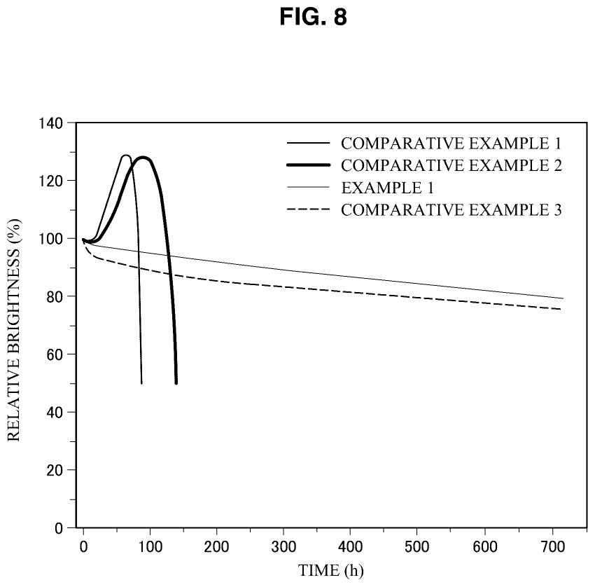

First, brightness stability of the organic EL elements according to Example 1 and Comparative Examples 1 to 3 was evaluated. Specifically, currents for each organic EL element were adjusted to set an initial brightness to 1000 cd/m², and the brightness stability was evaluated by continuously emitting light at a constant current in an environment of 25° C. and 50RH %. FIG. 8 shows changes in the brightness of each organic EL element over time. In FIG. 8, the brightness of each organic EL element is shown as a relative brightness with the initial brightness being 100%.

As shown in FIG. 8, in the organic EL elements according to Comparative Examples 1 and 2, it is difficult to sufficiently prevent external moisture or oxygen from entering the organic EL element, and thus the organic layer of the organic EL element deteriorates, and the brightness drops to 50% or less within 100 hours.

On the other hand, the organic EL element according to Example 1 can sufficiently prevent external moisture or oxygen from entering the organic EL element, and thus, similar to the organic EL element according to Comparative Example 3 sealed with a glass substrate, approximately 80% brightness can be maintained even after 700 hours.

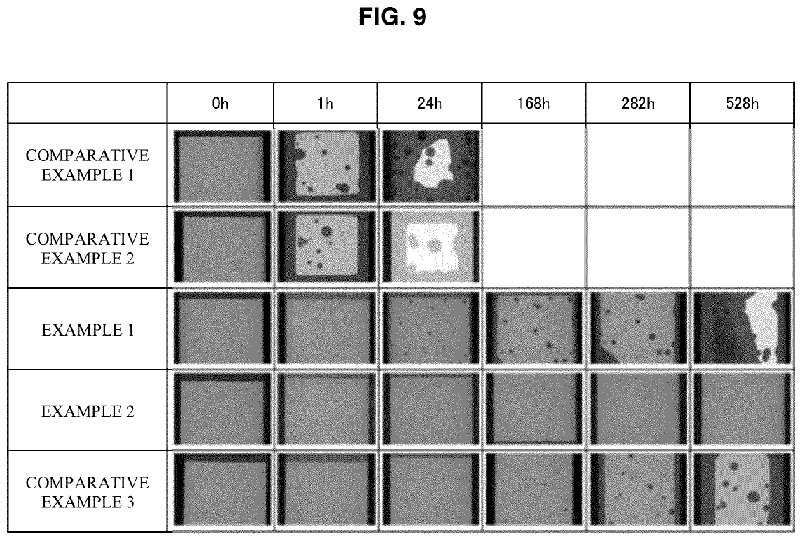

Next, sealing reliability of the organic EL elements according to Examples 1 to 2 and Comparative Examples 1 to 3 was evaluated. Specifically, the sealing reliability of the organic EL elements was evaluated by performing an accelerated deterioration test in which each organic EL element was left in an environment of 60° C. and 90% RH. FIG. 9 shows changes in a light-emitting region (2.0 mm×1.5 mm) of the organic EL elements over time.

As shown in FIG. 9, in the organic EL elements according to Comparative Examples 1 and 2, it is difficult to sufficiently prevent external moisture or oxygen from entering the organic EL elements, and thus black spots and shrinkage occur in the light-emitting region after 1 hour.

On the other hand, the organic EL elements according to Examples 1 and 2 can sufficiently prevent external moisture or oxygen from entering the organic EL element, and thus generation of black spots and shrinkage in the light-emitting region can be inhibited for a longer period of time than in the organic EL elements according to Comparative Examples 1 and 2. In particular, the organic EL element according to Example 2 was able to inhibit generation of black spots and shrinkage in the light-emitting region for a longer period of time than the organic EL element according to Comparative Example 3, which was sealed with a glass substrate.

As explained above, the organic EL elements according to Examples 1 and 2 can more reliably prevent external moisture or oxygen from entering the organic EL elements than the organic EL elements according to Comparative Examples 1 and 2. According to this, the organic EL elements according to Examples 1 and 2 can further improve the brightness stability and the sealing reliability.

Heretofore, preferred embodiments of the present invention have been described in detail with reference to the appended drawings, but the present invention is not limited thereto. It should be understood by those skilled in the art that various changes and alterations may be made without departing from the spirit and scope of the appended claims.

### REFERENCE SIGNS LIST

Organic EL element 100
Base material 110
Stress relaxation layer 120
Barrier layer 130
Multilayer sealing film 140
Inkjet head 210
Polymer material 211
Inorganic material 212
Light source 220
Vacuum ultraviolet rays 221

1. A method for sealing an organic EL element, comprising:
forming a stress relaxation layer by at least applying a polymer material that contains an organic group in its structure onto a base material, on which the organic EL element is provided, to cover the organic EL element; and
forming a barrier layer by at least applying an inorganic material on the stress relaxation layer, thereby forming a multilayer sealing film that includes the stress relaxation layer and the barrier layer.

2. The method for sealing an organic EL element according to claim 1, wherein the polymer material and the inorganic material are applied onto the base material by inkjet printing.

3-5. (canceled)

6. The method for sealing an organic EL element according to claim 1, wherein the multilayer sealing film seals the organic EL element by covering upper and side surfaces of the organic EL element.

7. The method for sealing an organic EL element according to claim 6, wherein the multilayer sealing film has a three-dimensional shape tapered in a direction away from a main surface of the base material.

8. (canceled)

9. (canceled)

10. The method for sealing an organic EL element according to claim 1, wherein the polymer material is applied using a solvent in which the polymer material has a higher solubility than that of the organic EL element.

11. The method for sealing an organic EL element according to claim 10, wherein decamethylcyclopentasiloxane is added to the solvent.

12. (canceled)

13. The method for sealing an organic EL element according to claim 1, wherein the polymer material includes polydimethylsiloxane.

14. The method for sealing an organic EL element according to claim 1, wherein a thickness of the stress relaxation layer is 50 nm or more and 500 nm or less.

15. The method for sealing an organic EL element according to claim 1, wherein a refractive index of the stress relaxation layer is 1.4 or more and 1.5 or less.

16. The method for sealing an organic EL element according to claim 1, wherein the stress relaxation layer includes a solid film of the polymer material that is irradiated with vacuum ultraviolet rays including light with a wavelength of 172 nm.

17. The method for sealing an organic EL element according to claim 16, wherein an accumulated light amount of the vacuum ultraviolet rays radiated onto the solid film is 15000 mJ/cm² or more.

18. The method for sealing an organic EL element according to claim 1, wherein the inorganic material is applied using a solvent in which the inorganic material has a higher solubility than that of the polymer material.

19. The method for sealing an organic EL element according to claim 1, wherein the inorganic material includes perhydropolysilazane.

20. The method for sealing an organic EL element according to claim 1, wherein a thickness of the barrier layer is 50 nm or more and 300 nm or less.

21. The method for sealing an organic EL element according to claim 1, wherein a refractive index of the barrier layer is 1.6 or more.

22. The method for sealing an organic EL element according to claim 1, wherein the barrier layer includes an applied film of the inorganic material that is cured by being irradiated with vacuum ultraviolet rays including light with a wavelength of 172 nm.

23. The method for sealing an organic EL element according to claim 22, wherein an accumulated light amount of the vacuum ultraviolet rays radiated onto the applied film is 15000 mJ/cm² or more.

24. The method for sealing an organic EL element according to claim 1, wherein the multilayer sealing film includes the stress relaxation layer and the barrier layer, which are alternately laminated in a plurality of layers.

25. The method for sealing an organic EL element according to claim 24, wherein a number of repeated layers of the stress relaxation layer and the barrier layer is 2 or more and 4 or less.

26. (canceled)

27. The method for sealing an organic EL element according to claim 1, wherein the stress relaxation layer and the barrier layer are formed under a nitrogen atmosphere.

28-30. (canceled)
